(19) United States
(12) Patent Application Publication
(10) Pub. No.: US 2024/0061456 A1
(43) Pub. Date: Feb. 22, 2024

(54) LOW DROPOUT (LDO) REGULATOR AND ELECTRONIC DEVICE INCLUDING THE SAME

(71) Applicant: SAMSUNG ELECTRONICS CO., LTD., SUWON-SI (KR)

(72) Inventors: DONGHA LEE, SUWON-SI (KR); SEKI KIM, SUWON-SI (KR); TAKAHIRO NOMIYAMA, SUWON-SI (KR)

(21) Appl. No.: 18/355,514

(22) Filed: Jul. 20, 2023

(30) Foreign Application Priority Data
Aug. 22, 2022 (KR) 10-2022-0104914

(51) Int. Cl. G05F 1/575; G05F 1/565; G05F 1/46

(52) U.S. Cl. CPC G05F 1/575; G05F 1/565; G05F 1/462

(57) ABSTRACT

A low dropout (LDO) regulator includes comparison circuitry configured to generate a comparison result signal by comparing a target voltage with an output voltage corresponding to an output voltage of an output terminal connected to an integrated circuit, voltage increase/decrease detection circuitry configured to generate a detection result signal by detecting whether the output voltage increases or decreases, control circuitry configured to generate a current control code having a value that is changed, based on a control mode selected according to the comparison result signal and the detection result signal, and current driving circuitry configured to receive the current control code and generate an output current corresponding to the current control code.

### CROSS-REFERENCE TO RELATED APPLICATION

This application is based on and claims priority under 35 U.S.C. § 119 to Korean Patent Application No. 10-2022-0104914, filed on Aug. 22, 2022 in the Korean Intellectual Property Office, the disclosure of which is incorporated by reference herein in its entirety.

### TECHNICAL FIELD

Embodiments of the inventive concept relate to a low dropout (LDO) regulator, and more particularly, to an LDO regulator and an electronic device including the LDO regulator.

### DISCUSSION OF RELATED ART

Along with the increasing degree of integration of integrated circuits and the increasing operation speed thereof, the amount of currents consumed by integrated circuits has been increased. Some high-performance integrated circuits, such as processing cores, may utilize high currents to function properly, and thus, the drop amount of output voltages of LDO regulators supplying power to integrated circuits may increase. To adjust dropped output voltages to target voltages, LDO regulators (or digital LDO regulators) may control output currents by switching between the turning on and off of power transistors.

### SUMMARY

Embodiments of the inventive concept provide a low dropout (LDO) regulator, which may allow an output voltage thereof to quickly and stably converge on a target voltage by performing a regulating operation on the output voltage based on a change direction of the output voltage, and an electronic device including the LDO regulator.

According to an embodiment of the inventive concept, there is provided an LDO regulator, which includes comparison circuitry configured to generate a comparison result signal by comparing a target voltage with an output voltage corresponding to an output voltage of an output terminal connected to an integrated circuit, voltage increase/decrease detection circuitry configured to generate a detection result signal by detecting whether the output voltage increases or decreases, control circuitry configured to generate a current control code having a value that is changed, based on a control mode selected according to the comparison result signal and the detection result signal, and current driving circuitry configured to receive the current control code, and generate an output current corresponding to the current control code.

According to an embodiment of the inventive concept, there is provided an electronic device including an LDO regulator and an integrated circuit configured to perform a certain operation by receiving an output voltage of the LDO regulator. The LDO regulator is configured to select one of a plurality of control modes based on a detection result signal, which is generated by detecting whether the output voltage increases or decreases, and a comparison result signal, which is generated by comparing a target voltage with the output voltage, and to supply an output current to the integrated circuit by controlling the output current based on the selected control mode.

According to an embodiment of the inventive concept, there is provided an electronic device including an LDO regulator and an integrated circuit configured to perform a certain operation by receiving an output voltage of the LDO regulator. The LDO regulator is configured to check a difference between the output voltage and a target voltage and a change direction of the output voltage by monitoring the output voltage, and to supply an output current to the integrated circuit by controlling the output current based on a result of checking the voltage difference and the change direction.

### BRIEF DESCRIPTION OF THE DRAWINGS

The above and other features of the present inventive concept will become more apparent by describing in detail embodiments thereof with reference to the accompanying drawings, in which:

FIG. 1 is a block diagram schematically illustrating an electronic device according to an embodiment;

FIGS. 2A to 2C are block diagrams respectively illustrating implementation examples of a low dropout (LDO) regulator of FIG. 1;

FIG. 3 is a flowchart illustrating a method of operating an LDO regulator, according to an embodiment;

FIG. 4 is a flowchart illustrating a method of operating an LDO regulator, according to an embodiment;

FIG. 5 is a diagram illustrating a regulating operation of an LDO regulator according to an output voltage, according to an embodiment;

FIGS. 6A and 6B are diagrams illustrating operations of an LDO regulator, according to an embodiment;

FIGS. 7A and 7B are diagrams illustrating operations of an LDO regulator, according to an embodiment;

FIGS. 8A to 8C are diagrams respectively illustrating implementation examples of voltage increase/decrease detection circuitry of FIG. 2A;

FIGS. 9A and 9B are block diagrams illustrating an implementation example of control circuitry of FIG. 2A;

FIGS. 10A and 10B are block diagrams illustrating an implementation example of control circuitry of FIG. 2C;

FIG. 11 is a block diagram illustrating an implementation example of control circuitry according to an embodiment;

FIG. 12 is a block diagram illustrating an application processor according to an embodiment;

FIGS. 13A and 13B are each a diagram illustrating operations of an LDO regulator, according to an embodiment;

FIG. 14 is a flowchart illustrating a method of operating an LDO regulator, according to an embodiment;

FIGS. 15A and 15B are diagrams illustrating operations of an LDO regulator, according to an embodiment; and

FIG. 16 is a block diagram illustrating an electronic device according to an embodiment.

### DETAILED DESCRIPTION OF THE EMBODIMENTS

Embodiments of the present inventive concept will be described more fully hereinafter with reference to the accompanying drawings. Like reference numerals may refer to like elements throughout the accompanying drawings.

It will be understood that the terms “first,” “second,” “third,” etc. are used herein to distinguish one element from another, and the elements are not limited by these terms. Thus, a “first” element in an embodiment may be described as a “second” element in another embodiment.

It should be understood that descriptions of features or aspects within each embodiment should typically be considered as available for other similar features or aspects in other embodiments, unless the context clearly indicates otherwise.

As used herein, the singular forms “a”, “an” and “the” are intended to include the plural forms as well, unless the context clearly indicates otherwise.

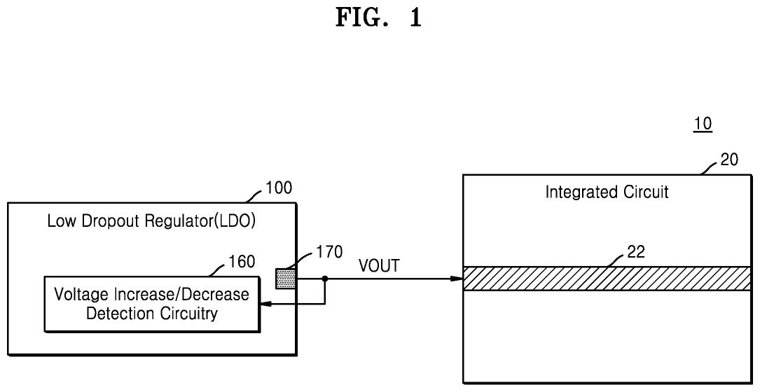

FIG. 1 is a block diagram schematically illustrating an electronic device 10 according to an embodiment. FIG. 1 omits some components of the electronic device 10 for convenience of explanation. For example, according to embodiments, the electronic device 10 may further include components not illustrated in FIG. 1, such as other low dropout (LDO) regulators and other integrated circuits.

Referring to FIG. 1, the electronic device 10 may include an integrated circuit 20 and an LDO regulator 100.

The integrated circuit 20 may include semiconductor circuits fabricated to be integrated in a semiconductor die. The integrated circuit 20 may correspond to one of various semiconductor integrated circuits, such as, for example, a central processing unit (CPU), a graphics processing unit (GPU), a system-on-chip (SoC), a memory controller, and a display controller. In addition, depending upon the function, area, design method, and the like of the integrated circuit 20, the integrated circuit 20 may be connected to at least one other LDO regulator, to which embodiments of the inventive concept are applied, rather than the LDO regulator 100, and thus supplied with power from the at least one other LDO regulator.

A power rail 22 may be formed on the integrated circuit 20 by using a conductive material. The power rail 22 may be connected to at least two points of the integrated circuit 20 and may appropriately distribute the power, which is supplied from the LDO regulator 100, to the integrated circuit 20.

In an embodiment, the LDO regulator 100 may include voltage increase/decrease detection circuitry 160 and an output terminal 170. The LDO regulator 100 may provide an output voltage VOUT to the integrated circuit 20 through the output terminal 170 and may regulate the output voltage VOUT such that the output voltage VOUT converges on a target voltage. For example, in a period (hereinafter, referred to as an undershoot period) in which the output voltage VOUT is lower than the target voltage, the LDO regulator 100 may control an output current, which is supplied to the integrated circuit 20 through the output terminal 170, to increase, and thus, the output voltage VOUT may increase toward the target voltage. In addition, in a period (hereinafter, referred to as an overshoot period) in which the output voltage VOUT is higher than the target voltage, the LDO regulator 100 may control the output current, which is supplied to the integrated circuit 20 through the output terminal 170, to decrease, and thus, the output voltage VOUT may decrease toward the target voltage. Herein, a regulating operation of the LDO regulator 100 on the output voltage VOUT may include an operation, performed by the LDO regulator 100, of controlling the output current provided to the integrated circuit 20 by the LDO regulator.

In an embodiment, to perform an operation of regulating the output voltage VOUT, the LDO regulator 100 may consider a change direction of the output voltage VOUT. Herein, the change direction of the output voltage VOUT may refer to an increase or decrease trend regarding whether the output voltage VOUT is increasing or decreasing.

In an embodiment, the voltage increase/decrease detection circuitry 160 may generate a detection result signal by detecting whether the output voltage VOUT increases or decreases, in synchronization with a certain clock signal. The LDO regulator 100 may select one of a plurality of control modes based on a state of the output voltage VOUT and on the detection result signal, and thus control the output current based on the selected control mode. In an embodiment, the plurality of control modes may include a fast mode and a slow mode. However, these are only examples, and embodiments of the inventive concept are not limited thereto. That is, the LDO regulator 100 may select one of the plurality of control modes by additionally considering a change-direction magnitude as well as the change direction of the output voltage VOUT, and thus perform a regulating operation on the output voltage VOUT. Hereinafter, for convenience of explanation, operations of the LDO regulator 100 will be described mainly based on the fast mode and the slow mode.

The LDO regulator 100 may regulate the output voltage VOUT toward the target voltage relatively more quickly in the fast mode than in the slow mode. To this end, the LDO regulator 100 may set at least one parameter for the regulation of the output voltage V OUT to different values respectively in the fast mode and in the slow mode. In an embodiment, the at least one parameter may include at least one of a parameter regarding a step height of the output current and a parameter regarding a change frequency of the output current, both controlled by the LDO regulator 100. In addition, the at least one parameter may vary depending on configurations for controlling the output current of the LDO regulator 100.

In an embodiment, when the output voltage VOUT decreases in the undershoot period in which the output voltage VOUT is lower than the target voltage, or when the output voltage VOUT increases in the overshoot period in which the output voltage VOUT is higher than the target voltage, the LDO regulator 100 may select the fast mode and thus regulate the output voltage VOUT based on the fast mode. In addition, when the output voltage VOUT increases in the undershoot period, or when the output voltage VOUT decreases in the overshoot period, the LDO regulator 100 may select the slow mode and thus regulate the output voltage VOUT based on the slow mode.

In an embodiment, the LDO regulator 100 may regulate the output voltage VOUT based on an operation mode of the integrated circuit 20. The LDO regulator 100 may change the value of the at least one parameter for the regulation of the output voltage VOUT in at least one of the fast mode and the slow mode by considering the operation mode of the integrated circuit 20. For example, in the fast mode, the LDO regulator 100 may change the value of the at least one parameter for the regulation of the output voltage VOUT such that the output voltage VOUT is more quickly regulated toward the target voltage when the integrated circuit 20 is in a high power mode than when the integrated circuit 20 is in a low power mode. However, this is only an example, and embodiments of the inventive concept are not limited thereto. That is, the LDO regulator 100 may regulate the output voltage VOUT by adaptively changing the value of the at least one parameter in a control mode, according to the operation mode of the integrated circuit 20.

The LDO regulator 100 according to an embodiment may select a control mode by considering whether the output voltage VOUT increases or decreases and may regulate the output voltage VOUT based on the selected control mode, whereby the output voltage VOUT may stably and quickly converge on the target voltage. By doing this, the LDO regulator 100 may stably supply the target voltage to the integrated circuit 20, and the integrated circuit 20 may smoothly operate, and the performance of the electronic device 10 may increase.

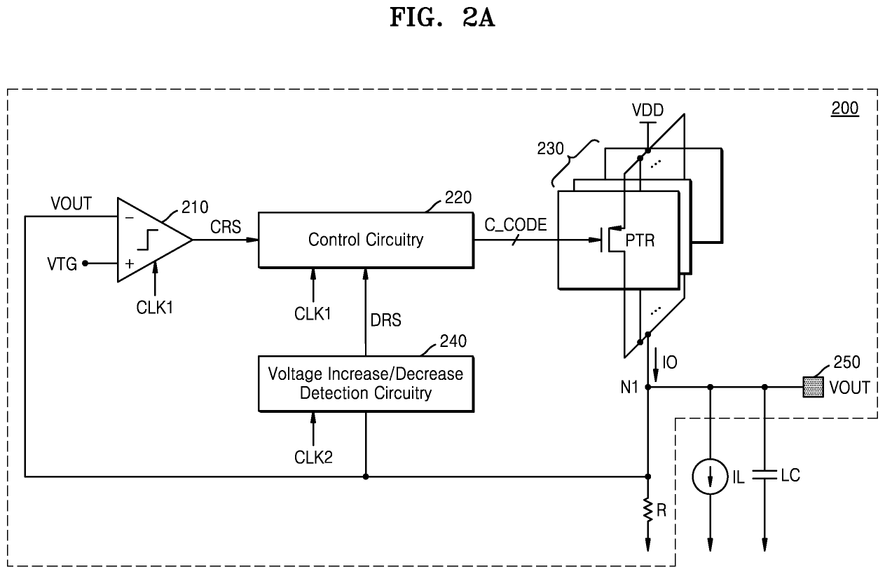

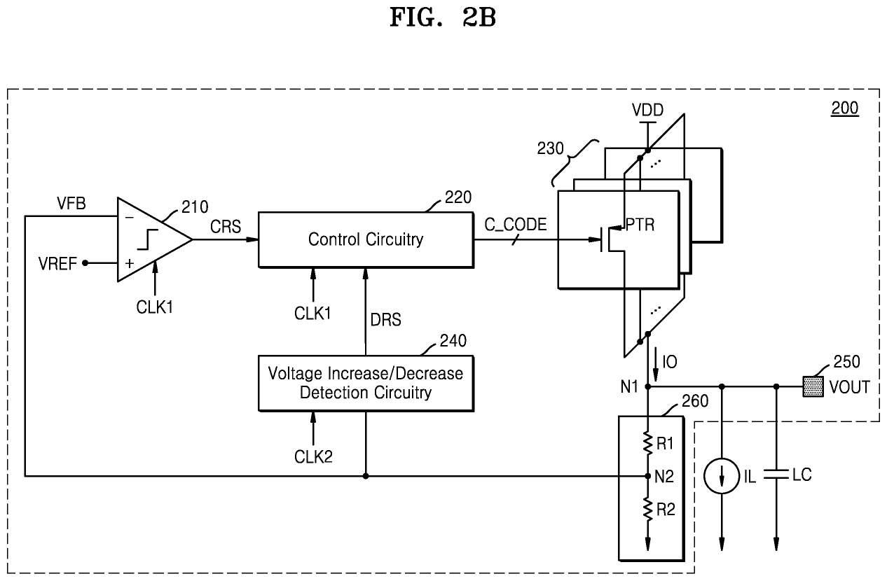

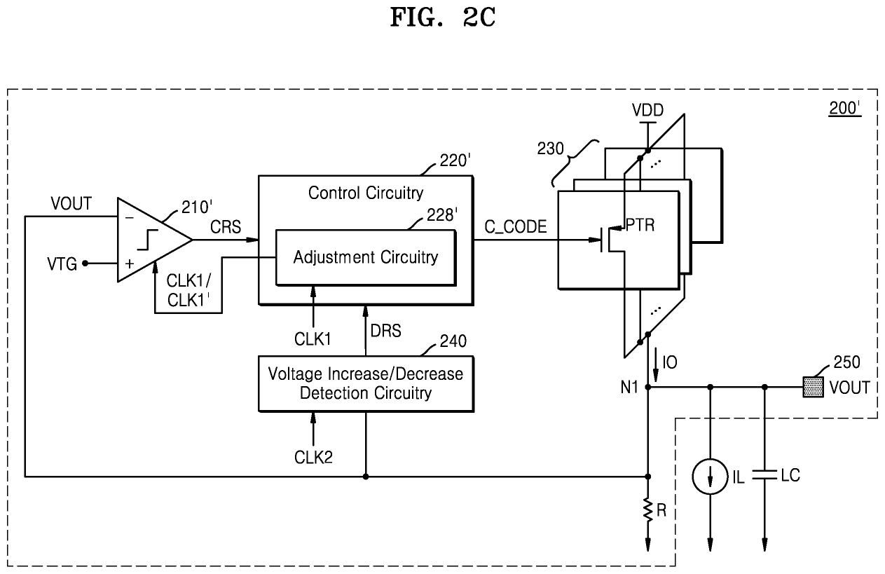

FIGS. 2A to 2C are block diagrams respectively illustrating implementation examples 200 and 200′ of the LDO regulator 100 of FIG. 1. It is to be understood that embodiments of the inventive concept are not limited to the examples of the LDO regulators 200 and 200′ illustrated in FIGS. 2A to 2C, and that embodiments of the inventive concept may also be applied to variously implemented LDO regulators.

Referring to FIG. 2A, the LDO regulator 200 may include comparison circuitry 210, control circuitry 220, current driving circuitry 230, voltage increase/decrease detection circuitry 240, an output terminal 250, and a resistor R. The LDO regulator 200 may be connected to the integrated circuit 20 (FIG. 1) via the output terminal 250, and this may be organized in the form of an equivalent circuit in which a current source corresponding to a load current IL flowing through the integrated circuit 20 (FIG. 1) is connected, via a first node N1, to a load capacitor LC corresponding to the capacitance of the integrated circuit 20 (FIG. 1).

In an embodiment, the comparison circuitry 210 may receive the output voltage VOUT and a target voltage VTG, and generate a comparison result signal CRS by comparing the output voltage VOUT with the target voltage VTG. For example, the comparison circuitry 210 may be implemented as an amplifier that amplifies a voltage difference between the output voltage VOUT and the target voltage VTG, and thus may output the amplified voltage difference as the comparison result signal CRS. The comparison circuitry 210 may generate the comparison result signal CRS in synchronization with a first clock signal CLK1.

In an embodiment, the voltage increase/decrease detection circuitry 240 may generate a detection result signal DRS by detecting whether the output voltage VOUT increases or decreases. The voltage increase/decrease detection circuitry 240 may generate the detection result signal DRS in synchronization with a second clock signal CLK2.

In some embodiments, the first clock signal CLK1 and the second clock signal CLK2 may be equal in frequency to each other. In some embodiments, the first clock signal CLK1 and the second clock signal CLK2 may be different in frequency from each other. For example, the second clock signal CLK2 may have a higher frequency than the first clock signal CLK1. As a result, the voltage increase/decrease detection circuitry 240 may relatively accurately detect a period in which the output voltage VOUT increases, and a period in which the output voltage VOUT decreases, by sensitively monitoring a change of the output voltage VOUT. As another example, the second clock signal CLK2 may have a lower frequency than the first clock signal CLK1. As a result, power consumed by the voltage increase/decrease detection circuitry 240 may be reduced.

In an embodiment, the control circuitry 220 may select one of a plurality of control modes based on the comparison result signal CRS received from the comparison circuitry 210 and on the detection result signal DRS received from the voltage increase/decrease detection circuitry 240, and may generate a current control code C_CODE changed in value, based on the selected control mode.

In an embodiment, the control circuitry 220 may select the fast mode, when the output voltage VOUT decreases in the undershoot period in which the output voltage VOUT is lower than the target voltage VTG, or when the output voltage VOUT increases in the overshoot period in which the output voltage VOUT is higher than the target voltage VTG. In addition, the control circuitry 220 may select the slow mode, when the output voltage VOUT increases in the undershoot period, or when the output voltage VOUT decreases in the overshoot period.

In an embodiment, the control circuitry 220 may generate the current control code C_CODE by increasing at least one of the number of bits, which are changed in values at once from among a plurality of bits in the current control code C_CODE, and a change frequency of the value of the current control code C_CODE. The number of bits and the change frequency may correspond to the aforementioned parameters for the regulation of the output voltage VOUT. For example, the number of bits may be set to 1 in the slow mode and may be set to 3 in the fast mode. For example, the change frequency may be set to once per unit time in the slow mode and may be set to three times per unit time in the fast mode. However, the examples set forth above are just examples, and embodiments of the inventive concept are not limited thereto.

In an embodiment, the control circuitry 220 may generate the current control code C_CODE in synchronization with the first clock signal CLK1. In some embodiments, the control circuitry 220 may change the frequency of the first clock signal CLK1 such that the change frequency of the value of the current control code C_CODE varies with a control mode, and may generate the current control code C_CODE in synchronization with the changed first clock signal CLK1. This will be described below in detail with reference to FIG. 2C.

In an embodiment, the current driving circuitry 230 may include a plurality of power transistors PTR, which are turned on/off respectively in response to a plurality of bits in the current control code C_CODE. The plurality of power transistors PTR may be connected in parallel with each other between the control circuitry 220 and the output terminal 250. For example, a gate terminal of a power transistor PTR may be connected to the control circuitry 220, a source terminal of the power transistor PTR may be connected to a power supply voltage VDD, and a drain terminal of the power transistor PTR may be connected to the first node N1.

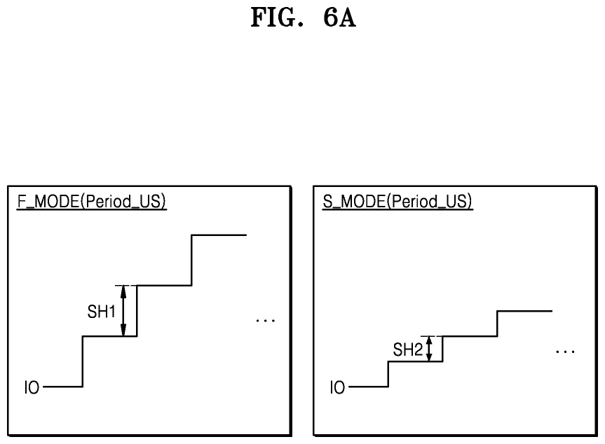

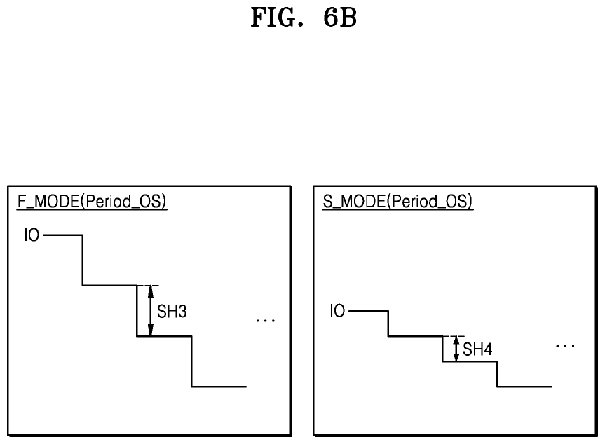

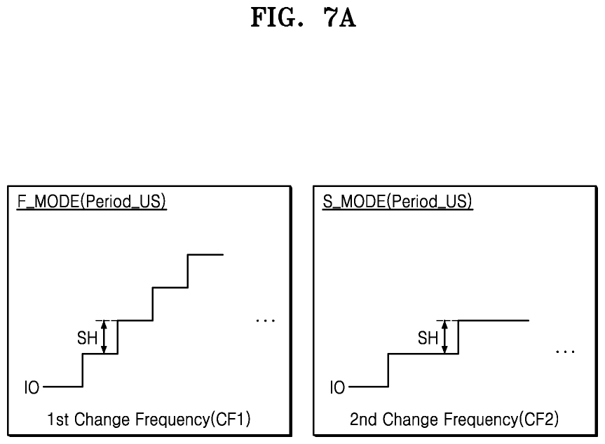

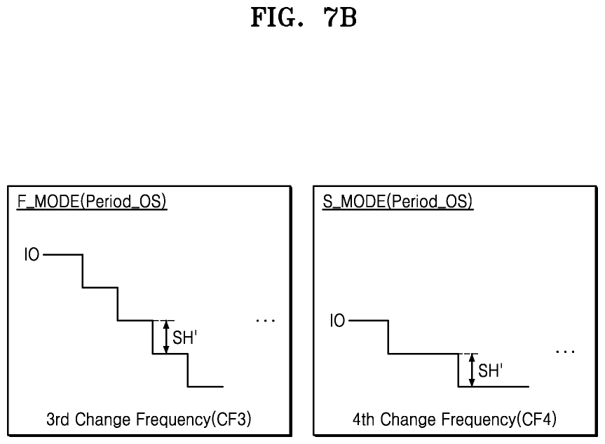

In an embodiment, the current driving circuitry 230 may generate an output current IO, which increases or decreases in a stepwise manner, in response to a change of the value of the current control code C_CODE, and may provide the output current IO to the integrated circuit 20 (FIG. 1). For example, the current driving circuitry 230 may generate the output current IO that increases or decreases in a stepwise manner more quickly in the fast mode than in the slow mode. This will be described below in detail with reference to FIGS. 6A to 7B.

The LDO regulator 200 according to an embodiment may quickly and stably perform a regulating operation on the output voltage VOUT by adaptively controlling a change rate of the output current IO based on the change direction of the output voltage VOUT, in response to a case in which the output voltage VOUT deviates from the target voltage VTG due to a sharp increase or decrease in the load current IL of the integrated circuit 20 (FIG. 1).

Referring to FIG. 2B, the LDO regulator 200 may further include voltage divider circuitry 260. The voltage divider circuitry 260 may be connected between the first node N1 and a ground terminal, and may divide the output voltage VOUT and provide a divided output voltage as a feedback voltage VFB to the comparison circuitry 210. For example, the voltage divider circuitry 260 may include a first resistor R1 and a second resistor R2 and may output the feedback voltage VFB through a second node N2. The comparison circuitry 210 may receive a reference voltage VREF together with the feedback voltage VFB and may generate the comparison result signal CRS by comparing the feedback voltage VFB with the reference voltage VREF. The reference voltage VREF may be determined to correspond to the target voltage VTG (FIG. 2A).

Referring to FIG. 2C, the control circuitry 220′ may include adjustment circuitry 228′. In an embodiment, the adjustment circuitry 228′ may generate a changed first clock signal CLK1′ by changing the frequency of the first clock signal CLK1 based on a certain adjustment ratio. For example, the adjustment circuitry 228′ may divide or multiply the frequency of the first clock signal CLK1 by a certain adjustment ratio.

In an embodiment, the control circuitry 220′ may generate the current control code C_CODE in synchronization with the first clock signal CLK1, in a first control mode, and may generate the current control code C_CODE in synchronization with the changed first clock signal CLK1′, in a second control mode.

The control circuitry 220′ may selectively provide one of the first clock signal CLK1 and the changed first clock signal CLK1′ to comparison circuitry 210′, based on a selected control mode. For example, when the control circuitry 220′ operates in synchronization with the first clock signal CLK1 in the first control mode, the control circuitry 220′ may provide the first clock signal CLK1 to the comparison circuitry 210′, and when the control circuitry 220′ operates in synchronization with the changed first clock signal CLK1′ in the second control mode, the control circuitry 220′ may provide the changed first clock signal CLK1′ to the comparison circuitry 210′.

In an embodiment, the control circuitry 220′ may control the change frequency of the output current by selectively using one of the first clock signal CLK1 and the changed first clock signal CLK1′ according to a selected control mode.

Although FIG. 2C illustrates that the control circuitry 220′ includes the adjustment circuitry 228′, embodiments are not limited thereto. For example, in some embodiments, the adjustment circuitry 228′ may be implemented as an independent component from the control circuitry 220′.

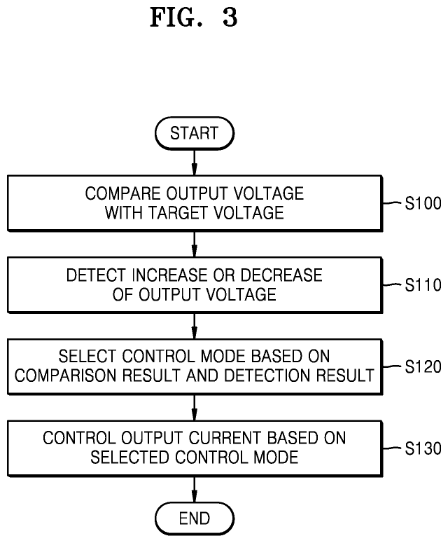

FIG. 3 is a flowchart illustrating a method of operating an LDO regulator, according to an embodiment. Hereinafter, although determining the undershoot period or the overshoot period by comparing an output voltage with a target voltage is mainly described, this is only an example, and embodiments of the inventive concept are not limited thereto. For example, the LDO regulator may determine, as the undershoot period, an occasion where the output voltage is lower than a lower limit of a target range, may determine, as the overshoot period, an occasion where the output voltage is higher than an upper limit of the target range, and may determine, as a period in which the output voltage is regulated to be maintained, an occasion where the output voltage is within the target range, according to embodiments.

Referring to FIG. 3, in operation S100, the LDO regulator may compare the output voltage with the target voltage. For example, the LDO regulator may check whether the output voltage is lower than the target voltage, whether the output voltage is higher than the target voltage, or whether the output voltage is maintained at the target voltage, by monitoring the target voltage provided to an integrated circuit through an output terminal. The LDO regulator may detect the undershoot period or the overshoot period by comparing the output voltage with the target voltage.

In operation S110, the LDO regulator may detect an increase or decrease of the output voltage. For example, the LDO regulator may check whether the output voltage is increased or decreased as compared with the previous output voltage, by monitoring the output voltage.

In operation S120, the LDO regulator may select a control mode based on a comparison result of operation S100 and a detection result of operation S110. For example, the LDO regulator may select the fast mode when the output voltage VOUT decreases in the undershoot period or increases in the overshoot period, and may select the slow mode when the output voltage VOUT increases in the undershoot period or decreases in the overshoot period.

In operation S130, the LDO regulator may control the output current based on the control mode selected in operation S120. For example, in the LDO regulator, at least one of the step height and the change frequency of the output current that increases or decreases in a stepwise manner in the fast mode may be greater than at least one of the step height and the change frequency of the output current that increases or decreases in a stepwise manner in the slow mode. That is, the LDO regulator may more quickly regulate the output voltage in the fast mode than in the slow mode.

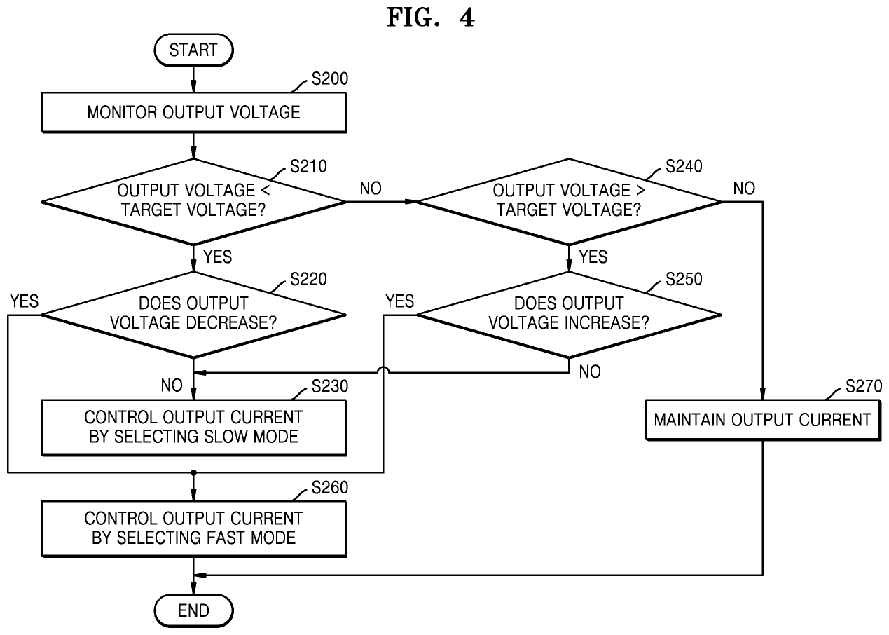

FIG. 4 is a flowchart illustrating a method of operating an LDO regulator, according to an embodiment.

Referring to FIG. 4, in operation S200, the LDO regulator may monitor an output voltage provided to an integrated circuit.

In operation S210, the LDO regulator may determine whether the output voltage is lower than a target voltage. That is, the LDO regulator may determine whether the output voltage is in the undershoot period.

When operation S210 results in “YES”, the method proceeds to operation S220, and the LDO regulator may determine whether the output voltage is decreased as compared with the previous output voltage.

When operation S220 results in “NO”, the method proceeds to operation S230, and the LDO regulator may control the output current by selecting the slow mode.

When operation S210 results in “NO”, the method proceeds to operation S240, and the LDO regulator may determine whether the output voltage is higher than the target voltage. That is, the LDO regulator may determine whether the output voltage is in the overshoot period.

When operation S240 results in “YES”, the method proceeds to operation S250, and the LDO regulator may determine whether the output voltage increases.

When operation S250 results in “NO”, the method proceeds to operation S230, and the LDO regulator may control the output current by selecting the slow mode.

When operation S220 or S250 results in “YES”, the method proceeds to operation S260, and the LDO regulator may control the output current by selecting the fast mode.

When operation S240 results in “NO”, the method proceeds to operation S270, and the LDO regulator may maintain the output current.

Although determining the undershoot period or the overshoot period by comparing the output voltage with the target voltage is mainly described with reference to FIG. 4, this is only an example, and embodiments of the inventive concept are not limited thereto. For example, the LDO regulator may determine, as the undershoot period, an occasion where the output voltage is lower than a lower limit of a target range, may determine, as the overshoot period, an occasion where the output voltage is higher than an upper limit of the target range, and may determine, as a period in which the output voltage is regulated to be maintained, an occasion where the output voltage is within the target range, according to embodiments.

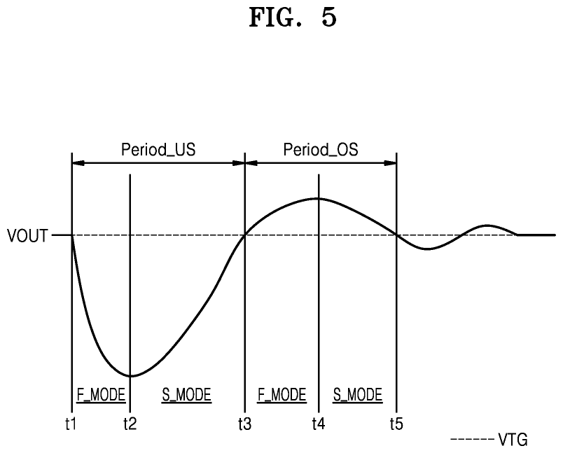

FIG. 5 is a diagram illustrating a regulating operation of an LDO regulator according to the output voltage VOUT.

Referring to FIG. 5, in an undershoot period Period_US in which the output voltage VOUT is lower than the target voltage VTG, the LDO regulator may select a control mode based on the change direction of the output voltage VOUT. For example, from a first time t1 to a second time t2, in which the output voltage VOUT decreases in the undershoot period Period_US, the LDO regulator may select a fast mode F_MODE and thus perform a regulating operation that may prevent or reduce a decrease of the output voltage VOUT, based on the fast mode F_MODE. In addition, from the second time t2 to a third time t3, in which the output voltage VOUT increases in the undershoot period Period_US, the LDO regulator may select a slow mode S_MODE and thus perform a regulating operation that may increase the output voltage VOUT toward the target voltage VTG, based on the slow mode S_MODE.

From the third time t3 to a fourth time t4, in which the output voltage VOUT increases in an overshoot period Period_OS, the LDO regulator may select the fast mode F_MODE and thus perform a regulating operation which may prevent or reduce a decrease of the output voltage VOUT, based on the fast mode F_MODE. In addition, from the fourth time t4 to a fifth time t5, in which the output voltage VOUT decreases in the overshoot period Period_OS, the LDO regulator may select the slow mode S_MODE and thus perform a regulating operation which may decrease the output voltage VOUT toward the target voltage VTG, based on the slow mode S_MODE.

FIGS. 6A and 6B are diagrams illustrating operations of an LDO regulator, according to an embodiment.

Referring to FIG. 6A, in the undershoot period Period_US, the LDO regulator may select one of the fast mode F_MODE and the slow mode S_MODE based on the change direction of the output voltage VOUT, and may control the output current IO to increase in a stepwise manner while having a preset step height according to a selected control mode.

For example, in the fast mode F_MODE, the LDO regulator may control the output current IO to increase in a stepwise manner while having a first step height SH1. In the slow mode S_MODE, the LDO regulator may control the output current IO to increase in a stepwise manner while having a second step height SH2 that is lower than the first step height SH1.

Referring to FIG. 6B, in the overshoot period Period_OS, the LDO regulator may select one of the fast mode F_MODE and the slow mode S_MODE based on the change direction of the output voltage VOUT, and may control the output current IO to decrease in a stepwise manner while having a preset step height according to a selected control mode.

For example, in the fast mode F_MODE, the LDO regulator may control the output current IO to decrease in a stepwise manner while having a third step height SH3. In the slow mode S_MODE, the LDO regulator may control the output current IO to decrease in a stepwise manner while having a fourth step height SH4 that is lower than the third step height SH3.

In an embodiment, the first step height SH1 may be equal to or different from the third step height SH3. For example, the LDO regulator may set the first step height SH1 and the third step height SH3 in the fast mode F_MODE to be equal to each other. As another example, the LDO regulator may set the first step height SH1 and the third step height SH3 in the fast mode F_MODE to be different from each other. For example, the LDO regulator may set the first step height SH1 to be higher than the third step height SH3. On the contrary, the LDO regulator may set the first step height SH1 to be lower than the third step height SH3.

In an embodiment, the second step height SH2 may be equal to or different from the fourth step height SH4. For example, the LDO regulator may set the second step height SH2 and the fourth step height SH4 in the slow mode S_MODE to be equal to each other. As another example, the LDO regulator may set the second step height SH2 and the fourth step height SH4 in the slow mode S_MODE to be different from each other. For example, the LDO regulator may set the second step height SH2 to be higher than the fourth step height SH4. On the contrary, the LDO regulator may set the second step height SH2 to be lower than the fourth step height SH4.

FIGS. 7A and 7B are diagrams illustrating operations of an LDO regulator, according to an embodiment.

Referring to FIG. 7A, in the undershoot period Period_US, the LDO regulator may select one of the fast mode F_MODE and the slow mode S_MODE based on the change direction of the output voltage VOUT, and may control the output current IO to increase in a stepwise manner while having a preset change frequency according to a selected control mode.

For example, in the fast mode F_MODE, the LDO regulator may control the output current IO to increase in a stepwise manner by a fifth step height SH while having a first change frequency CF1. In the slow mode S_MODE, the LDO regulator may control the output current IO to increase in a stepwise manner by the fifth step height SH while having a second change frequency CF2 that is lower than the first change frequency CF1.

Referring FIG. 7B, in the overshoot period Period_OS, the LDO regulator may select one of the fast mode F_MODE and the slow mode S_MODE based on the change direction of the output voltage VOUT, and may control the output current IO to decrease in a stepwise manner while having a preset change frequency according to a selected control mode.

For example, in the fast mode F_MODE, the LDO regulator may control the output current IO to decrease in a stepwise manner by a sixth step height SH′ while having a third change frequency CF3. In the slow mode S_MODE, the LDO regulator may control the output current IO to decrease in a stepwise manner by the sixth step height SH′ while having a fourth change frequency CF4 that is lower than the third change frequency CF3.

In an embodiment, the first change frequency CF1 may be equal to or different from the third change frequency CF3. For example, the LDO regulator may set the first change frequency CF1 and the third change frequency CF3 in the fast mode F_MODE to be equal to each other. As another example, the LDO regulator may set the first change frequency CF1 and the third change frequency CF3 in the fast mode F_MODE to be different from each other. For example, the LDO regulator may set the first change frequency CF1 to be higher than the third change frequency CF3. On the contrary, the LDO regulator may set the first change frequency CF1 to be lower than the third change frequency CF3.

In an embodiment, the second change frequency CF2 may be equal to or different from the fourth change frequency CF4. For example, the LDO regulator may set the second change frequency CF2 and the fourth change frequency CF4 in the slow mode S_MODE to be equal to each other. As another example, the LDO regulator may set the second change frequency CF2 and the fourth change frequency CF4 in the slow mode S_MODE to be different from each other. For example, the LDO regulator may set the second change frequency CF2 to be higher than the fourth change frequency CF4. On the contrary, the LDO regulator may set the second change frequency CF2 to be lower than the fourth change frequency CF4.

In an embodiment, the fifth step height SH may be equal to or different from the sixth step height SH′.

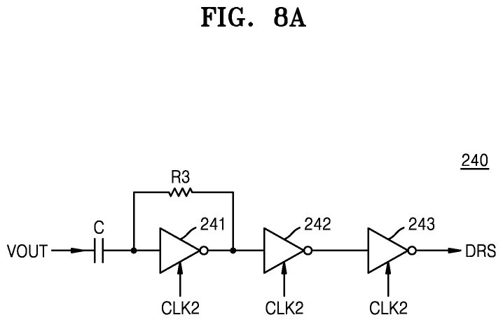

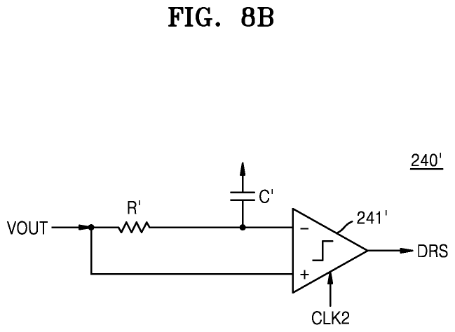

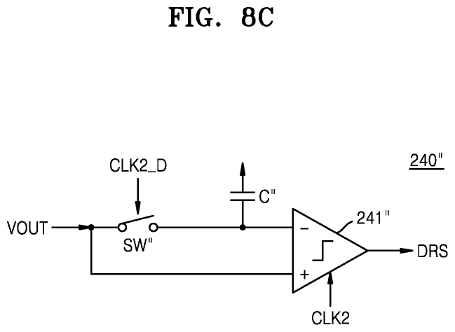

FIGS. 8A to 8C are diagrams respectively illustrating implementation examples of the voltage increase/decrease detection circuitry 240 of FIG. 2A.

It is to be understood that the implementation examples of the voltage increase/decrease detection circuitry 240 of FIG. 2A are just examples, and embodiments of the inventive concept are not limited thereto. For example, the voltage increase/decrease detection circuitry 240 may be variously implemented to perform a detection operation on the change direction of the output voltage VOUT, according to embodiments of the inventive concept.

Referring to FIG. 8A, the voltage increase/decrease detection circuitry 240 may include a capacitor C, a resistor R3, and first, second, and third inverting amplifiers 241, 242, and 243. The output voltage VOUT may be input to one end of the capacitor C, and the other end of the capacitor C may be connected to one end of the resistor R3 and an input of the first inverting amplifier 241. The resistor R3 may be connected in parallel with the first inverting amplifier 241. The other end of the resistor R3 and an output of the first inverting amplifier 241 may be connected to an input of the second inverting amplifier 242. The output of the second inverting amplifier 242 may be connected to an input of the third inverting amplifier 243.

For example, the capacitor C, the resistor R3, and the first inverting amplifier 241 may differentiate the output voltage VOUT in synchronization with the second clock signal CLK2. The second inverting amplifier 242 and the third inverting amplifier 243 may amplify, in the stated order, a differentiation result signal, which is output from the first inverting amplifier 241, in synchronization with the second clock signal CLK2, thereby outputting the amplified differentiation result signal as the detection result signal DRS. In an embodiment, each of the second inverting amplifier 242 and the third inverting amplifier 243 may have a certain amplifier gain such that the control circuitry 220 (FIG. 2A) may clearly identify whether the differentiation result signal has a positive value or a negative value.

In some embodiments, when an LDO regulator is implemented as shown in FIG. 2B, the feedback voltage VFB may be input to the capacitor C of the voltage increase/decrease detection circuitry 240.

Referring to FIG. 8B, voltage increase/decrease detection circuitry 240′ may include a resistor R′, a capacitor C′, and a comparator 241′. As one end of the resistor R′ is connected to a positive input terminal of the comparator 241′, the output voltage VOUT may be input to the positive input terminal of the comparator 241′, and the other end of the resistor R′ may be connected to one end of the capacitor C′ and a negative input terminal of the comparator 241′. The other end of the capacitor C′ may be grounded.

The output voltage VOUT may be delayed by as much as a certain phase due to the resistor R′ and the capacitor C′, and then be applied to the negative input terminal of the comparator 241′. The comparator 241′ may generate the detection result signal DRS, which indicates whether the output voltage VOUT increases or decreases, by comparing the delayed output voltage VOUT with the current output voltage VOUT, in synchronization with the second clock signal CLK2.

Referring to FIG. 8C, voltage increase/decrease detection circuitry 240″ may include a switch SW″, a capacitor C″, and a comparator 241″. As one end of the switch SW″ is connected to a positive input terminal of the comparator 241″, the output voltage VOUT may be input to the positive input terminal of the comparator 241″, and the other end of the switch SW″ may be connected to one end of the capacitor C″ and a negative input terminal of the comparator 241″. The other end of the capacitor C″ may be grounded.

The switch SW″ may be turned on or off in synchronization with a second clock signal CLK2_D delayed from the second clock signal CLK2. The output voltage VOUT may be delayed by as much as a certain phase, based on a sample and hold operation using the switch SW″ and the capacitor C″, and then be applied to the negative input terminal of the comparator 241″. The comparator 241″ may generate the detection result signal DRS, which indicates whether the output voltage VOUT increases or decreases, by comparing the delayed output voltage VOUT with the current output voltage VOUT, in synchronization with the second clock signal CLK2.

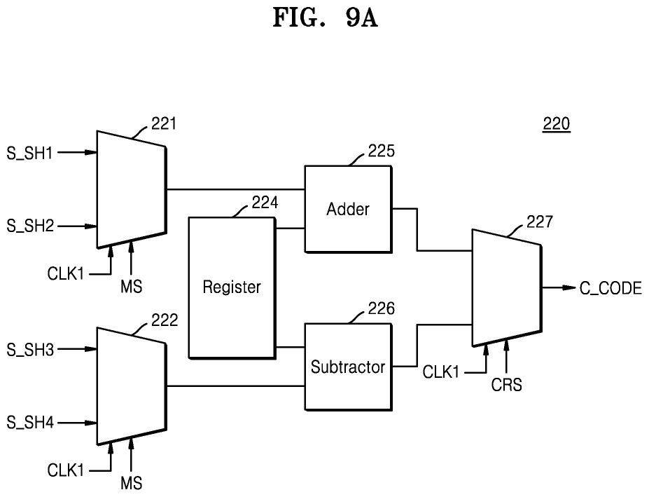

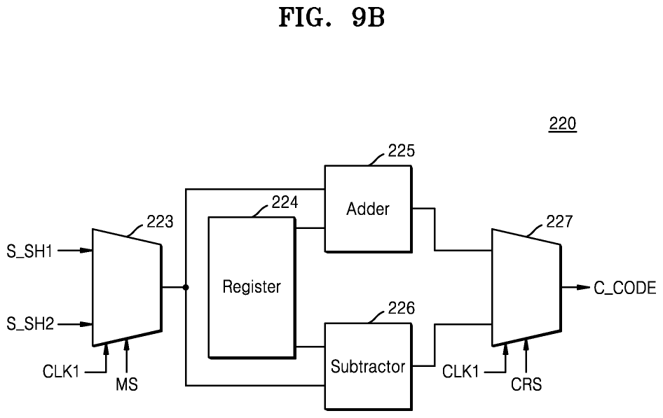

FIGS. 9A and 9B block diagrams illustrating an implementation example of the control circuitry 220 of FIG. 2A. The control circuitry 220 of each of FIGS. 9A and 9B may be an implementation example associated with FIGS. 6A and 6B. A first step height signal S_SH1 of FIG. 9A may correspond to the first step height SH1 of FIG. 6A, a second step height signal S_SH2 of FIG. 9A may correspond to the second step height SH2 of FIG. 6A, a third step height signal S_SH3 of FIG. 9A may correspond to the third step height SH3 of FIG. 6B, and a fourth step height signal S_SH4 of FIG. 9A may correspond to the fourth step height SH4 of FIG. 6B. In an example described with reference to FIG. 9B, the first step height SH1 of FIG. 6A is equal to the third step height SH3 of FIG. 6B, and the second step height SH2 of FIG. 6A is equal to the fourth step height SH4 of FIG. 6B. However, the implementation example of the control circuitry 220 of each of FIGS. 9A and 9B is only an example, and embodiments of the inventive concept are not limited thereto. For example, the control circuitry 220 may be variously implemented to perform an operation according to embodiments of the inventive concept.

Referring to FIG. 9A, the control circuitry 220 may include first, second, and third multiplexers 221, 222, and 227, a register 224, an adder 225, and a subtractor 226.

The first multiplexer 221 may output, to the adder 225, one of the first step height signal S_SH1 and the second step height signal S_SH2, which are received, based on a mode signal MS, in synchronization with the first clock signal CLK1. The mode signal MS may be a signal indicating the fast mode or the slow mode. For example, the first multiplexer 221 may output the first step height signal S_SH1 in the fast mode and may output the second step height signal S_SH2 in the slow mode.

The second multiplexer 222 may output, to the subtractor 226, one of the third step height signal S_SH3 and the fourth step height signal S_SH4, which are received, based on the mode signal MS, in synchronization with the first clock signal CLK1. For example, the second multiplexer 222 may output the third step height signal S_SH3 in the fast mode and may output the fourth step height signal S_SH4 in the slow mode.

The register 224 may store the value of the current control code C_CODE, which is output by the third multiplexer 227, and may provide the stored value to the adder 225 and the subtractor 226.

The adder 225 may add the value of the current control code C_CODE stored in the register 224 to an output of the first multiplexer 221. For example, the adder 225 may add the value of the current control code C_CODE stored in the register 224 to the first step height signal S_SH1 in the fast mode, and may add the value of the current control code C_CODE stored in the register 224 to the second step height signal S_SH2 in the slow mode.

The subtractor 226 may subtract an output of the second multiplexer 222 from the value of the current control code C_CODE stored in the register 224. For example, the subtractor 226 may subtract the third step height signal S_SH3 from the value of the current control code C_CODE stored in the register 224, in the fast mode, and may subtract the fourth step height signal S_SH4 from the value of the current control code C_CODE stored in the register 224, in the slow mode.

The third multiplexer 227 may produce, as the current control code C_CODE that is changed in value, one of the output of the adder 225 and the output of the subtractor 226, which are received, based on the comparison result signal CRS, in synchronization with the first clock signal CLK1. For example, the third multiplexer 227 may produce the output of the adder 225 as the current control code C_CODE in the undershoot period in which an output voltage is lower than a target voltage, and may produce the output of the subtractor 226 as the current control code C_CODE in the overshoot period in which the output voltage is higher than the target value. The latest value of the current control code C_CODE output from the third multiplexer 227 may be stored in the register 224.

Referring to FIG. 9B, the control circuitry 220 may include a fourth multiplexer 223, the register 224, the adder 225, the subtractor 226, and the third multiplexer 227. Hereinafter, a further description of components and technical aspects previously described with reference to FIG. 9A are omitted.

The fourth multiplexer 223 may output, to the subtractor 226, one of the first step height signal S_SH1 and the second step height signal S_SH2, which are received, based on the mode signal MS, in synchronization with the first clock signal CLK1. For example, the fourth multiplexer 223 may output the first step height signal S_SH1 in the fast mode and may output the second step height signal S_SH2 in the slow mode.

The register 224 may store the value of the current control code C_CODE, which is output by the third multiplexer 227, and may provide the stored value to the adder 225 and the subtractor 226.

The adder 225 may add the value of the current control code C_CODE stored in the register 224 to an output of the fourth multiplexer 223. For example, the adder 225 may add the value of the current control code C_CODE stored in the register 224 to the first step height signal S_SH1 in the fast mode, and may add the value of the current control code C_CODE stored in the register 224 to the second step height signal S_SH2 in the slow mode.

The subtractor 226 may subtract the output of the fourth multiplexer 223 from the value of the current control code C_CODE stored in the register 224. For example, the subtractor 226 may subtract the first step height signal S_SH1 from the value of the current control code C_CODE stored in the register 224, in the fast mode, and may subtract the second step height signal S_SH2 from the value of the current control code C_CODE stored in the register 224, in the slow mode.

The third multiplexer 227 may produce, as the current control code C_CODE that is changed in value, one of the output of the adder 225 and the output of the subtractor 226, which are received, based on the comparison result signal CRS, in synchronization with the first clock signal CLK1.

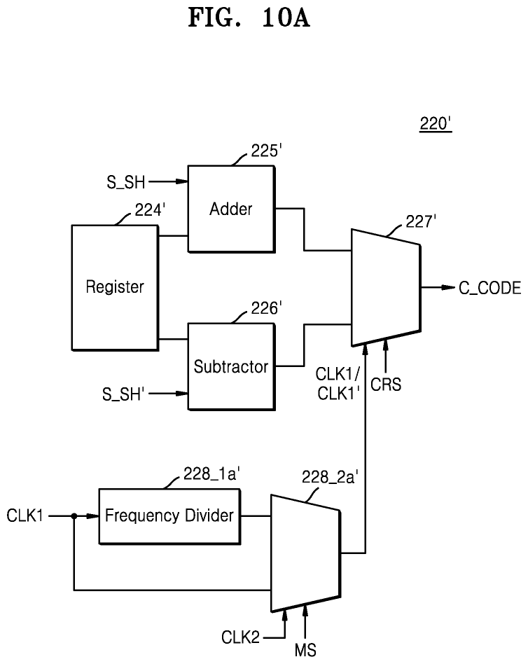

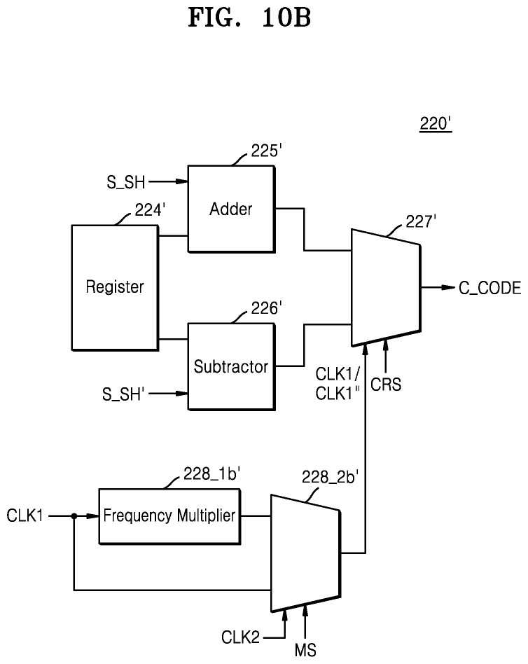

FIGS. 10A and 10B are block diagrams illustrating an implementation example of the control circuitry 220′ of FIG. 2C. The control circuitry 220′ of each of FIGS. 10A and 10B may be an implementation example associated with FIGS. 7A and 7B. A fifth step height signal S_SH of FIGS. 10A and 10B may correspond to the fifth step height SH of FIG. 7A, and a sixth step height signal S_SH′ of FIGS. 10A and 10B may correspond to the sixth step height SH′ of FIG. 7B. However, the implementation example of the control circuitry 220′ of each of FIGS. 10A and 10B is only an example, and embodiments of the inventive concept are not limited thereto. For example, the control circuitry 220′ may be variously implemented to perform a control operation according to embodiments of the inventive concept.

Referring to FIG. 10A, the control circuitry 220′ may include a register 224′, an adder 225′, a subtractor 226′, a third multiplexer 227′, a frequency divider 228_1a′, and a fifth multiplexer 228_2a′.

The register 224′ may store the value of the current control code C_CODE, which is output by the third multiplexer 227′, and may provide the stored value to the adder 225′ and the subtractor 226′.

The adder 225′ may add the value of the current control code C_CODE stored in the register 224′ to the fifth step height signal S_SH that is received.

The subtractor 226′ may subtract the sixth step height signal S_SH′ from the value of the current control code C_CODE stored in the register 224′.

The frequency divider 228_1a′ and the fifth multiplexer 228_2a′ may constitute the adjustment circuitry 228′ of FIG. 2C. The frequency divider 228_1a′ may output a first clock signal CLK1′ that is divided, by dividing the frequency of the first clock signal CLK1. The fifth multiplexer 228_2a′ may output, to the third multiplexer 227′, one of the first clock signal CLK1 and the divided first clock signal CLK1′, based on the mode signal MS, in synchronization with the second clock signal CLK2. For example, the fifth multiplexer 228_2a′ may output the first clock signal CLK1 in the fast mode and may output the divided first clock signal CLK1′ in the slow mode. In addition, the fifth multiplexer 228_2a′ may also output, to the comparison circuitry 210′ (FIG. 2C), the first clock signal CLK1 or the divided first clock signal CLK1′.

The third multiplexer 227′ may produce, as the current control code C_CODE that is changed in value, one of an output of the adder 225′ and an output of the subtractor 226′, which are received, based on the comparison result signal CRS, in synchronization with the first clock signal CLK1 or the divided first clock signal CLK1′. For example, the third multiplexer 227′ may produce the output of the adder 225′ as the current control code C_CODE, in synchronization with the first clock signal CLK1, when in the undershoot period in the fast mode, and may produce the output of the subtractor 226′ as the current control code C_CODE, in synchronization with the first clock signal CLK1, when in the overshoot period in the fast mode. For example, the third multiplexer 227′ may produce the output of the adder 225′ as the current control code C_CODE, in synchronization with the divided first clock signal CLK1′, when in the undershoot period in the slow mode, and may produce the output of the subtractor 226′ as the current control code C_CODE, in synchronization with the divided first clock signal CLK1′, when in the overshoot period in the slow mode.

Referring to FIG. 10B, the control circuitry 220′ may include the register 224′, the adder 225′, the subtractor 226′, the third multiplexer 227′, a frequency multiplier 228_1U, and a fifth multiplexer 228_2b′. Hereinafter, for convenience of explanation, a further description of components and technical aspects previously described with reference to FIG. 10A are omitted.

The frequency multiplier 228_1b′ and the fifth multiplexer 228_2b′ may constitute the adjustment circuitry 228′ of FIG. 2C. The frequency multiplier 228_1b′ may output a first clock signal CLK1″ that is multiplied, by multiplying the frequency of the first clock signal CLK1. The fifth multiplexer 228_2b′ may output, to the third multiplexer 227′, one of the first clock signal CLK1 and the multiplied first clock signal CLK1″, based on the mode signal MS, in synchronization with the second clock signal CLK2. For example, the fifth multiplexer 228_2b′ may output the multiplied first clock signal CLK1″ in the fast mode and may output the first clock signal CLK1 in the slow mode. In addition, the fifth multiplexer 228_2b′ may also output, to the comparison circuitry 210′ (FIG. 2C), the first clock signal CLK1 or the multiplied first clock signal CLK1″.

The third multiplexer 227′ may produce, as the current control code C_CODE that is changed in value, one of the output of the adder 225′ and the output of the subtractor 226′, which are received, based on the comparison result signal CRS, in synchronization with the first clock signal CLK1 or the multiplied first clock signal CLK1″. For example, the third multiplexer 227′ may produce the output of the adder 225′ as the current control code C_CODE, in synchronization with the multiplied first clock signal CLK1″, when in the undershoot period in the fast mode, and may produce the output of the subtractor 226′ as the current control code C_CODE, in synchronization with the multiplied first clock signal CLK1″, when in the overshoot period in the fast mode. For example, the third multiplexer 227′ may produce the output of the adder 225′ as the current control code C_CODE, in synchronization with the first clock signal CLK1, when in the undershoot period in the slow mode, and may produce the output of the subtractor 226′ as the current control code C_CODE, in synchronization with the first clock signal CLK1, when in the overshoot period in the slow mode.

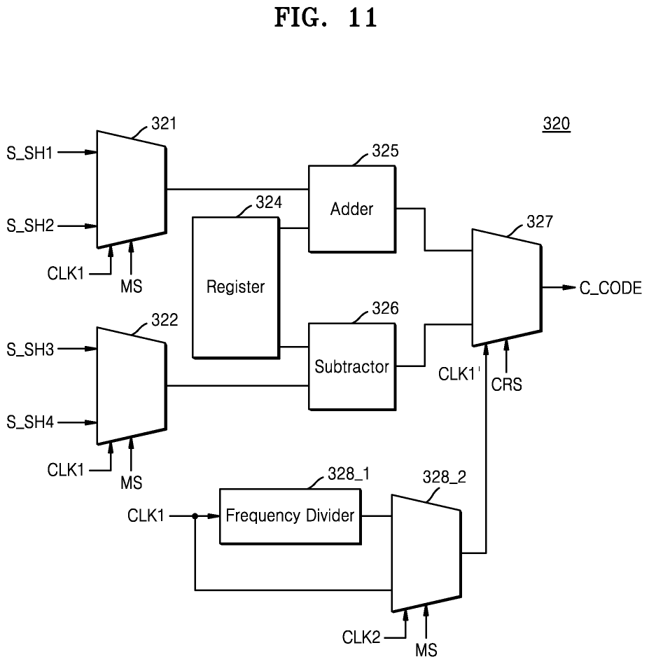

FIG. 11 is a block diagram illustrating an implementation example of control circuitry 320 according to an embodiment. FIG. 11 illustrates an implementation example of the control circuitry 320, in which the implementation examples of the control circuitry 220 and 220′ respectively described with reference to FIGS. 9A and 10A, are combined.

Referring to FIG. 11, the control circuitry 320 may include a first multiplexer 321, a second multiplexer 322, a third multiplexer 327, a fifth multiplexer 328_2, a register 324, an adder 325, a subtractor 326, and a frequency divider 328_1.

The first multiplexer 321 may output, to the adder 325, one of the first step height signal S_SH1 and the second step height signal S_SH2, which are received, based on the mode signal MS, in synchronization with the first clock signal CLK1. The mode signal MS may be a signal indicating the fast mode or the slow mode. For example, the first multiplexer 321 may output the first step height signal S_SH1 in the fast mode and may output the second step height signal S_SH2 in the slow mode.

The second multiplexer 322 may output, to the subtractor 326, one of the third step height signal S_SH3 and the fourth step height signal S_SH4, which are received, based on the mode signal MS, in synchronization with the first clock signal CLK1. For example, the second multiplexer 322 may output the third step height signal S_SH3 in the fast mode and may output the fourth step height signal S_SH4 in the slow mode.

The register 324 may store the value of the current control code C_CODE, which is output by the third multiplexer 327, and may provide the stored value to the adder 325 and the subtractor 326.

The adder 325 may add the value of the current control code C_CODE stored in the register 324 to an output of the first multiplexer 321. For example, the adder 325 may add the value of the current control code C_CODE stored in the register 324 to the first step height signal S_SH1 in the fast mode, and may add the value of the current control code C_CODE stored in the register 324 to the second step height signal S_SH2 in the slow mode.

The subtractor 326 may subtract an output of the second multiplexer 322 from the value of the current control code C_CODE stored in the register 324, in the fast mode. For example, the subtractor 326 may subtract the third step height signal S_SH3 from the value of the current control code C_CODE stored in the register 324, in the fast mode, and may subtract the fourth step height signal S_SH4 from the value of the current control code C_CODE stored in the register 324, in the slow mode.

The frequency divider 328_1 may output the first clock signal CLK1′ that is divided, by dividing the frequency of the first clock signal CLK1. The fifth multiplexer 328_2 may output, to the third multiplexer 327, one of the first clock signal CLK1 and the divided first clock signal CLK1′, based on the mode signal MS, in synchronization with the second clock signal CLK2. For example, the fifth multiplexer 328_2 may output the first clock signal CLK1 in the fast mode and may output the divided first clock signal CLK1′ in the slow mode.

The third multiplexer 327 may produce, as the current control code C_CODE that is changed in value, one of the output of the adder 325 and the output of the subtractor 326, which are received, based on the comparison result signal CRS, in synchronization with the first clock signal CLK1 or the divided first clock signal CLK1′.

According to an embodiment, a frequency divider and a frequency multiplier, as described above, may be combined to form a frequency divider/multiplier that may change the frequency of the first clock signal.

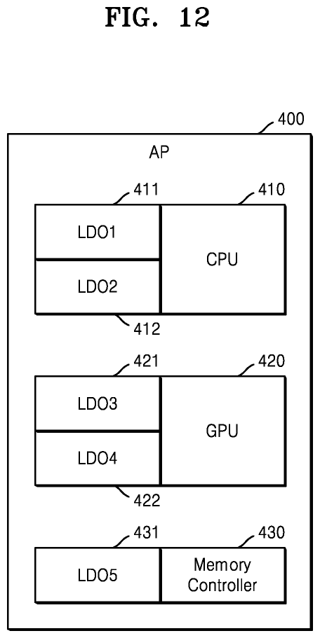

FIG. 12 is a block diagram illustrating an application processor 400 according to an embodiment.

Referring to FIG. 12, the application processor 400 may include first, second, third, fourth, and fifth LDO regulators 411, 412, 421, 422, and 431, a CPU 410, a GPU 420, and a memory controller 430.

The first and second LDO regulators 411 and 412 may be connected to the CPU 410 and respectively provide output voltages to the CPU 410. The first and second LDO regulators 411 and 412 may respectively generate output voltages at the same level or at different levels.

The third and fourth LDO regulators 421 and 422 may be connected to the GPU 420 and respectively provide output voltages to the GPU 420. The third and fourth LDO regulators 421 and 422 may respectively generate output voltages at the same level or at different levels.

The fifth LDO regulator 431 may be connected to the memory controller 430 and provide an output voltage to the memory controller 430.

In an embodiment, each of the first, second, third, fourth, and fifth LDO regulators 411, 412, 421, 422, and 431 may set a value of at least one parameter for regulating the output voltage thereof, based on an operation mode of an integrated circuit (the CPU 410, the GPU 420, or the memory controller 430) connected thereto. For example, when the operation mode of the CPU 410 includes a high power mode and a low power mode, the value of the at least one parameter may be set such that an output current may change more quickly in the fast mode corresponding to the high power mode of the CPU 410 than in the slow mode corresponding to the low power mode of the CPU 410.

Each of the CPU 410, the GPU 420, and the memory controller 430 may operate in the same operation mode or in one of different operation modes, and each of the first, second, third, fourth, and fifth LDO regulators 411, 412, 421, 422, and 431 may receive a signal regarding a current operation mode from the integrated circuit (the CPU 410, the GPU 420, or the memory controller 430) connected thereto.

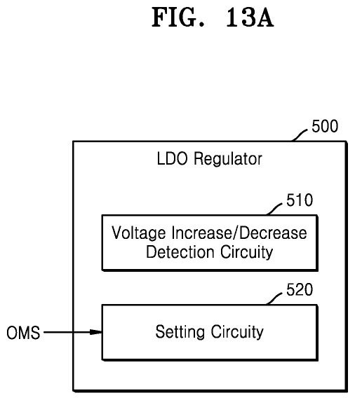

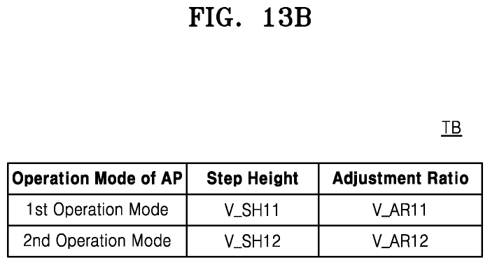

FIGS. 13A and 13B are diagrams illustrating operations of an LDO regulator 500, according to an embodiment.

Referring to FIG. 13A, the LDO regulator 500 may include current increase/decrease detection circuitry 510 and setting circuitry 520. In an embodiment, the setting circuitry 520 may receive an operation mode signal OMS regarding an operation mode from an integrated circuit connected to the LDO regulator 500, and based on the operation mode signal OMS, may set a value of at least one parameter for regulating an output voltage of the LDO regulator 500.

Referring to FIG. 13B, values of parameters, which are set by the setting circuitry 520 according to the operation mode of the integrated circuit, may be pre-arranged, as in Table TB. For example, the operation mode of the integrated circuit may include first and second operation modes, and the parameters may include a first parameter regarding a step height and a second parameter regarding an adjustment ratio. Herein, the adjustment ratio may be defined as a frequency ratio between the first clock signal CLK1 and the changed first clock signal CLK1′ in FIG. 2C.

In the first operation mode, the setting circuitry 520 may set the first parameter to a first value V_SH11 or may set the second parameter to a second value V_AR11. In addition, in the second operation mode, the setting circuitry 520 may set the first parameter to a third value V_SH12 or may set the second parameter to a fourth value V_AR12.

Although FIG. 13B illustrates only two operation modes and two parameters, this is only an example, and embodiments of the inventive concept are not limited thereto.

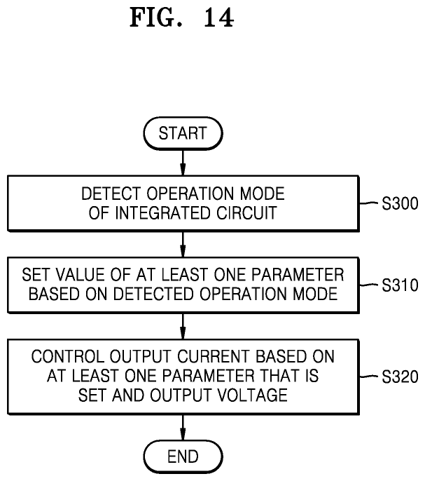

FIG. 14 is a flowchart illustrating a method of operating an LDO regulator, according to an embodiment.

Referring to FIG. 14, in operation S300, the LDO regulator may detect an operation mode of an integrated circuit.

In operation S310, the LDO regulator may set a value of at least one parameter based on the detected operation mode.

In operation S320, the LDO regulator may control an output current, based on the at least one parameter that is set and on an output voltage.

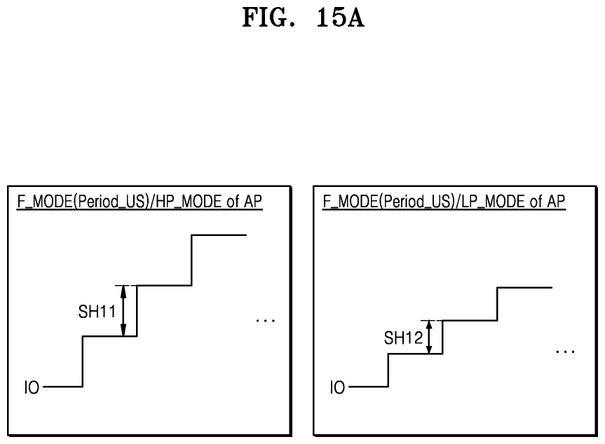

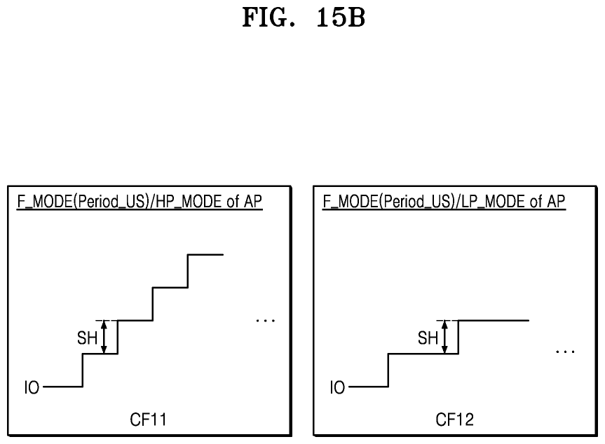

FIGS. 15A and 15B are diagrams illustrating operations of an LDO regulator, according to an embodiment. An embodiment according to each of FIGS. 15A and 15B may be associated with an embodiment according to FIG. 13B, and the LDO regulator may perform an operation based on Table TB. The first operation mode may be a high power mode HP_MODE, and the second operation mode may be a low power mode LP_MODE.

Referring to FIG. 15A, the LDO regulator may control the output current IO to increase in a stepwise manner while having an eleventh step height SH11, in a fast mode F_MODE in the undershoot period Period_US, when an operation mode of an integrated circuit is the high power mode HP_MODE. For example, the LDO regulator may control the output current IO to increase in a stepwise manner while having the eleventh step height SH11, by setting the first parameter regarding the step height to the first value V_SH11, as shown in FIG. 13B.

The LDO regulator may control the output current IO to increase in a stepwise manner while having a twelfth step height SH12, in the fast mode F_MODE in the undershoot period Period_US, when the operation mode of the integrated circuit is the low power mode LP_MODE. For example, the LDO regulator may control the output current IO to increase in a stepwise manner while having the twelfth step height SH12, by setting the first parameter to the second value V_SH12, as shown in FIG. 13B.

Referring to FIG. 15B, the LDO regulator may control the output current IO to increase in a stepwise manner at an eleventh change frequency CF11 while having a certain step height SH, in the fast mode F_MODE in the undershoot period Period_US, when the operation mode of the integrated circuit is the high power mode HP_MODE. For example, the LDO regulator may control the output current IO to increase in a stepwise manner at the eleventh change frequency CF11 while having the certain step height SH, by setting the second parameter regarding the adjustment ratio to the third value V_AR11, as shown in FIG. 13B.

The LDO regulator may control the output current IO to increase in a stepwise manner at a twelfth change frequency CF12 while having the certain step height SH, in the fast mode F_MODE in the undershoot period Period_US, when the operation mode of the integrated circuit is the low power mode LP_MODE. For example, the LDO regulator may control the output current IO to increase in a stepwise manner at the twelfth change frequency CF12 while having the certain step height SH, by setting the second parameter to the fourth value V_AR12, as shown in FIG. 13B.

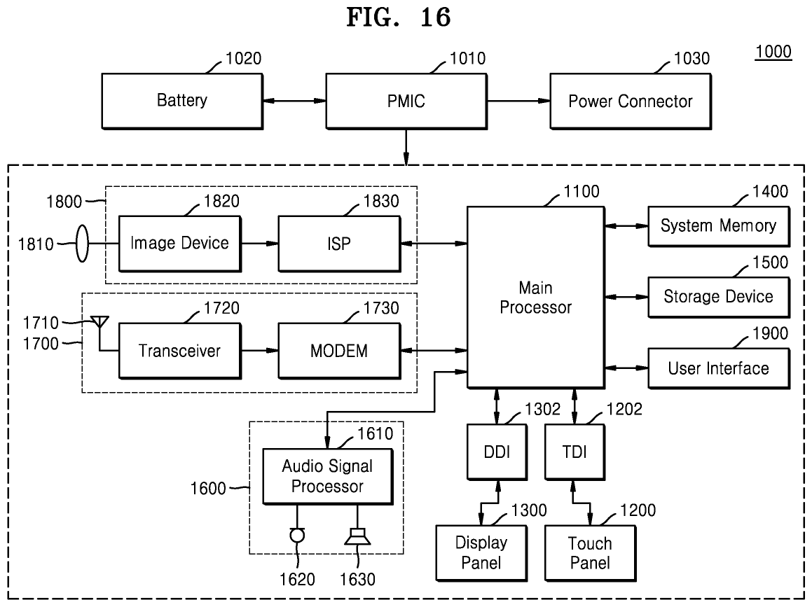

FIG. 16 is a block diagram illustrating an electronic device 1000 according to an embodiment.

Referring to FIG. 16, the electronic device 1000 may include a main processor 1100, a touch panel 1200, a touch driver integrated circuit (IC) (TDI) 1202, a display panel 1300, a display driver IC (DDI) 1302, a system memory 1400, a storage device 1500, an audio processor 1600, a communication block 1700, an image processor 1800, and a user interface 1900. In an embodiment, the electronic device 1000 may include one of various electronic devices, such as, for example, a personal computer, a laptop computer, a server, a workstation, a mobile communication terminal, a personal digital assistant (PDA), a portable media player (PMP), a digital camera, a smartphone, a tablet computer, and a wearable device.

The main processor 1100 may control overall operations of the electronic device 1000. The main processor 1100 may control/manage operations of the components of the electronic device 1000. The main processor 1100 may process various operations to operate the electronic device 1000. The touch panel 1200 may be configured to sense a touch input from a user according to control by the TDI 1202. The display panel 1300 may be configured to display image information according to control by the DDI 1302.

The system memory 1400 may store data used for operations of the electronic device 1000. For example, the system memory 1400 may include volatile memory, such as static random access memory (SRAM), dynamic RAM (DRAM), or synchronous DRAM (SDRAM), and/or nonvolatile memory, such as phase-change RAM (PRAM), magneto-resistive RAM (MRAM), resistive RAM (ReRAM), or ferro-electric RAM (FRAM).

The storage device 1500 may store data regardless of the supply of power. For example, the storage device 1500 may include at least one of various nonvolatile memory, such as flash memory, PRAM, MRAM, ReRAM, and FRAM. For example, the storage device 1500 may include embedded memory and/or removable memory of the electronic device 1000.

The audio processor 1600 may process audio signals by using an audio signal processor 1610. The audio processor 1600 may receive an audio input through a microphone 1620 or may provide an audio output through a speaker 1630.

The communication block 1700 may exchange signals with an external device/system through an antenna 1710. A transceiver 1720 and a modulator/demodulator (MODEM) 1730 of the communication block 1700 may process the signals exchanged with the external device/system, according to at least one of various wireless communication specifications, such as, for example, Long Term Evolution (LTE), Worldwide Interoperability for Microwave Access (WiMax), Global System for Mobile communication (GSM), Code Division Multiple Access (CDMA), Bluetooth, Near Field Communication (NFC), Wireless Fidelity (Wi-Fi), and Radio Frequency Identification (RFID).

The image processor 1800 may receive light through a lens 1810. An image device 1820 and an image signal processor (ISP) 1830, which are included in the image processor 1800, may generate image information about an external object, based on the received light. The user interface 1900 may include an interface capable of exchanging information with a user, except for the touch panel 1200, the display panel 1300, the audio processor 1600, and the image processor 1800. The user interface 1900 may include, for example, a keyboard, a mouse, a printer, a projector, various sensors, a human body communication device, and the like.

The electronic device 1000 may further include a power management IC (PMIC) 1010, a battery 1020, and a power connector 1030. The PMIC 1010 may generate internal power from power supplied from the battery 1020 or power supplied from the power connector 1030, and may provide the internal power to the main processor 1100, the tough panel 1200, the TDI 1202, the display panel 1300, the DDI 1302, the system memory 1400, the storage device 1500, the audio processor 1600, the communication block 1700, the image processor 1800, and the user interface 1900.

The electronic device 1000 may include LDO regulators according to some embodiments, and the LDO regulators may be connected to the components in the electronic device 1000 and perform regulating operations on output voltages by using change directions of the output voltages. By doing this, the components in the electronic device 1000 may be stably supplied with power from the LDO regulators.

The PMIC 1010 may perform dynamic voltage scaling (DVS) on semiconductor ICs. The PMIC 1010 may provide power supply voltages to the LDO regulators according to some embodiments.

Alternatively, the electronic device 1000 may be implemented by various mobile devices, such as, for example, a smartphone and a smartpad. In addition, the electronic device 1000 may be implemented by various wearable devices, such as, for example, a smart watch, smart glasses, and virtual reality goggles.

As is traditional in the field of the inventive concept, embodiments are described, and illustrated in the drawings, in terms of functional blocks, units and/or modules. Those skilled in the art will appreciate that these blocks, units and/or modules are physically implemented by electronic (or optical) circuits such as logic circuits, discrete components, microprocessors, hard-wired circuits, memory elements, wiring connections, etc., which may be formed using semiconductor-based fabrication techniques or other manufacturing technologies. In the case of the blocks, units and/or modules being implemented by microprocessors or similar, they may be programmed using software (e.g., microcode) to perform various functions discussed herein and may optionally be driven by firmware and/or software. Alternatively, each block, unit and/or module may be implemented by dedicated hardware, or as a combination of dedicated hardware to perform some functions and a processor (e.g., one or more programmed microprocessors and associated circuitry) to perform other functions.

For example, components according to embodiments of the inventive concept described herein may be referred to using blocks. The blocks may be implemented by various hardware devices, such as an IC, an application-specific IC (ASIC), a field programmable gate array (FPGA), and a complex programmable logic device (CPLD), firmware driven in hardware devices, software such as applications, or a combination of a hardware device and software. In addition, the blocks may include circuits constituted by semiconductor devices in ICs, or circuits registered as intellectual property (IP) blocks.

Referring to a comparative example, while methods employed may allow dropped output voltages to be quickly adjusted to target voltages, because power transistors operate in linear regions, the amount of current of power transistors may be significantly changed due to differences in drain-source voltages. Thus, in the comparative example, the stability of operation of power transistors may be deteriorated, and as a result, because output voltages of LDO regulators are not smoothly adjusted to converge on target voltages, power may not be stably supplied to integrated circuits in the comparative example. In contrast, embodiments of the present inventive concept may stably provide power to integrated circuits as described above, thus, increasing stability.

While the inventive concept has been particularly shown and described with reference to embodiments thereof, it will be understood that various changes in form and details may be made therein without departing from the spirit and scope of the inventive concept as defined by the following claims.

1. A low dropout (LDO) regulator, comprising:
comparison circuitry configured to generate a comparison result signal by comparing a target voltage with an output voltage corresponding to a voltage of an output terminal connected to an integrated circuit;
voltage increase/decrease detection circuitry configured to generate a detection result signal by detecting whether the output voltage increases or decreases;
control circuitry configured to generate a current control code having a value that is changed, based on a control mode selected according to the comparison result signal and the detection result signal; and
current driving circuitry configured to receive the current control code, and generate an output current corresponding to the current control code.

2. The LDO regulator of claim 1, wherein the selected control mode corresponds to a fast mode, when the output voltage decreases in an undershoot period in which the output voltage is lower than the target voltage, or when the output voltage increases in an overshoot period in which the output voltage is higher than the target voltage, and
the selected control mode corresponds to a slow mode, when the output voltage increases in the undershoot period, or when the output voltage decreases in the overshoot period.

3. The LDO regulator of claim 2, wherein the control circuitry is further configured to generate the current control code by causing at least one of a number of bits, which are changed in values at once from among a plurality of bits in the current control code, and a change frequency of the value of the current control code, to be greater in the fast mode than in the slow mode.

4. The LDO regulator of claim 2, wherein the current driving circuitry is further configured to:
generate the output current to increase in a stepwise manner while having a first step height, in response to a change in the value of the current control code, in the fast mode in the undershoot period; and
generate the output current to increase in the stepwise manner while having a second step height that is lower than the first step height, in response to the change in the value of the current control code, in the slow mode in the undershoot period.

5. The LDO regulator of claim 4, wherein the current driving circuitry is further configured to:
generate the output current to decrease in the stepwise manner while having a third step height, in response to the change in the value of the current control code, in the fast mode in the overshoot period; and
generate the output current to decrease in the stepwise manner while having a fourth step height that is lower than the third step height, in response to the change in the value of the current control code, in the slow mode in the overshoot period.

6. The LDO regulator of claim 5, wherein the first step height is different from the third step height, and
the second step height is different from the fourth step height.

7. The LDO regulator of claim 2, wherein the current driving circuitry is further configured to:
generate the output current to increase in a stepwise manner while having a first change frequency, in response to a change in the value of the current control code, in the fast mode in the undershoot period; and
generate the output current to increase in the stepwise manner while having a second change frequency that is lower than the first change frequency, in response to the change in the value of the current control code, in the slow mode in the undershoot period.

8. The LDO regulator of claim 7, wherein the current driving circuitry is further configured to:
generate the output current to decrease in the stepwise manner while having a third change frequency, in response to the change in the value of the current control code, in the fast mode in the overshoot period; and
generate the output current to decrease in the stepwise manner while having a fourth change frequency that is lower than the third change frequency, in response to the change in the value of the current control code, in the slow mode in the overshoot period.

9. The LDO regulator of claim 8, wherein the first change frequency is different from the third change frequency, and
the second change frequency is different from the fourth change frequency.

10. The LDO regulator of claim 1, wherein the control circuitry comprises:
a register configured to store the value of the current control code that is received by the current driving circuitry;
a first multiplexer configured to output one of a first step height signal and a second step height signal, based on the detection result signal;
an adder configured to add the value of the current control code stored in the register to an output of the first multiplexer;
a subtractor configured to subtract the output of the first multiplexer from the value of the current control code stored in the register; and
a second multiplexer configured to output, as the current control code having the value that is changed, one of an output of the adder and an output of the subtractor, based on the comparison result signal.

11. The LDO regulator of claim 1, wherein the control circuitry comprises:
a register configured to store the value of the current control code that is received by the current driving circuitry;
an adder configured to add the value of the current control code stored in the register to a step height signal;
a subtractor configured to subtract the step height signal from the value of the current control code stored in the register;
a frequency divider/multiplier configured to change a frequency of a first clock signal;
a first multiplexer configured to output one of the first clock signal before the frequency divider/multiplier changes the frequency and the first clock signal having the changed frequency, based on the detection result signal; and
a second multiplexer configured to output, as the current control code having the value that is changed, one of an output of the adder and an output of the subtractor, based on the comparison result signal, in synchronization with an output of the first multiplexer.

12. The LDO regulator of claim 1, wherein the voltage increase/decrease detection circuitry comprises:
a capacitor, to which the output voltage is input;
a first inverting amplifier connected in series with the capacitor;
a resistor connected in parallel with the first inverting amplifier; and
at least one second inverting amplifier connected in series with the first inverting amplifier and configured to output the detection result signal.

13. The LDO regulator of claim 1, wherein the voltage increase/decrease detection circuitry comprises:
a resistor, to which the output voltage is input;
a capacitor connected between the resistor and ground; and
a comparator comprising a positive input terminal, to which the output voltage is applied, and a negative input terminal, to which the output voltage delayed by a certain phase due to the resistor and the capacitor is applied.

14. The LDO regulator of claim 1, wherein the voltage increase/decrease detection circuitry comprises:
a switch, to which the output voltage is input;
a capacitor connected between the switch and ground; and
a comparator comprising a positive input terminal, to which the output voltage is applied, and a negative input terminal, to which the output voltage delayed by a certain phase due to the switch and the capacitor is applied.

15. The LDO regulator of claim 1, wherein the current driving circuitry comprises:
a plurality of power transistors configured to be turned on or off, respectively, in response to a plurality of bits in the current control code.

16. The LDO regulator of claim 1, further comprising:
parameter setting circuitry configured to set a value of at least one parameter used to change the value of the current control code, each in a plurality of control modes, based on an operation mode of the integrated circuit.

17. (canceled)

18. An electronic device, comprising:
a low dropout (LDO) regulator; and
an integrated circuit configured to perform a certain operation by receiving an output voltage of the LDO regulator,
wherein the LDO regulator is configured to:
select one of a plurality of control modes, based on a detection result signal, which is generated by detecting whether the output voltage increases or decreases, and a comparison result signal, which is generated by comparing the output voltage with a target voltage; and
supply an output current to the integrated circuit by controlling the output current based on the selected control mode.

19. The electronic device of claim 18, wherein the plurality of control modes comprise a fast mode and a slow mode, and
the LDO regulator is further configured to:
select the fast mode, when the output voltage decreases in an undershoot period in which the output voltage is lower than the target voltage, or when the output voltage increases in an overshoot period in which the output voltage is higher than the target voltage; and
select the slow mode, when the output voltage increases in the undershoot period, or when the output voltage decreases in the overshoot period.

20. (canceled)

21. (canceled)

22. The electronic device of claim 18, further comprising:
at least one other LDO regulator configured to supply another output voltage to the integrated circuit.

23-25. (canceled)

26. An electronic device, comprising:
a low dropout (LDO) regulator; and
an integrated circuit configured to perform a certain operation by receiving an output voltage of the LDO regulator,
wherein the LDO regulator is configured to:
check a voltage difference between the output voltage and a target voltage and a change direction of the output voltage by monitoring the output voltage; and
supply an output current to the integrated circuit by controlling the output current based on a result of checking the voltage difference and the change direction.
